(19) United States
(12) Patent Application Publication
(10) Pub. No.: US 2011/0005686 A1
(43) Pub. Date: Jan. 13, 2011

(54) LOADING TABLE STRUCTURE AND PROCESSING DEVICE

(75) Inventors: Sumi TANAKA, Yamanashi (JP); Tomohito KOMATSU, Yamanashi (JP); Hiroo KAWASAKI, Yamanashi (JP)

Correspondence Address: CANTOR COLBURN LLP, 20 Church Street, 22nd Floor, Hartford, CT, 06103, US

(73) Assignee: TOKYO ELECTRON LIMITED, Tokyo (JP)

(21) Appl. No.: 12/877,760

(22) Filed: Sep. 8, 2010

Related U.S. Application Data
(63) Continuation of application No. PCT/JP2009/054258, filed on Mar. 6, 2009.

(30) Foreign Application Priority Data
Mar. 11, 2008 (JP) 2008-061800
Sep. 30, 2008 (JP) 2008-254797

(51) Int. Cl. C23F 1/08; C23C 16/00; C23C 16/46

(52) U.S. Cl. 156/345.52; 118/725

(57) ABSTRACT

A loading table structure which is adapted, in order to prevent damage to the loading table, so that large thermal stress does not occur in the loading table and so that the amount of supply of a purge gas for corrosion prevention to the loading table is minimized. The loading table structure is formed in a processing container capable of discharging gas contained therein and is used to load thereon an object to be processed. The loading table structure is provided with a loading table on which the object to be processed is loaded and which consists of a dielectric, a heating means which is provided to the loading table and which heats the object to be processed loaded on the loading table, and protective strut tubes which are mounted so as to vertically rise from the bottom section of the processing container, which have upper ends joined to the lower surface of the loading table to support the loading table, and which consist of a dielectric. A functional bar extending up to the loading table is inserted into each protective strut tube.

### CROSS REFERENCE TO RELATED APPLICATIONS

This is a Continuation Application of International Application No. PCT/JP2009/054258, filed on 6 Mar. 2009. Priority under 35 U.S.C. §119(a) and 35 U.S.C. §365(b) is claimed from Japanese Application No. 2008-061800, filed 11 Mar. 2008 and Japanese Application No. 2008-254797, filed 30 Sep., 2008 the disclosure of which is also incorporated herein by reference.

### TECHNICAL FIELD

The present invention relates to a loading table structure and a device for processing an object to-be-processed, such as a semiconductor wafer.

### BACKGROUND ART

In general, in the process of manufacturing a semiconductor integrated circuit, various sheet fed treatments, such as a film formation, etching, thermal processing, reforming, and crystallization, are performed for an object to be processed, such as a semiconductor wafer. By these treatments, a desired integrated circuit is formed. In performing various sheet fed treatments as described above, a processing gas corresponding to the type of the treatment is introduced into a processing container. For example, a film forming gas or halogen gas in the case of film formation, an ozone gas in the case of reforming, and an O₂ gas or an inert gas, such as N₂ gas, in the case of crystallization, are introduced into a processing container, respectively.

For example, a sheet fed type processing apparatus for performing a thermal processing of a semiconductor wafer one sheet by one sheet has a loading table equipped with, for example, an embedded resistance heater, disposed within a processing container capable of performing vacuum discharge. In the case of performing a thermal processing of a wafer in such a processing apparatus, a semiconductor wafer is disposed on an upper surface of a loading table and is heated to a predetermined temperature (for example, about 100° C. to 1000° C.), and a predetermined processing gas flows around the semiconductor wafer. In this way, the wafer is subjected to various heat treatments under predetermined process conditions (see Patent documents 1 to 6). Therefore, members within a processing container are required to have a thermal resistance against heating of the members and a corrosion resistance capable of preventing corrosion of the members even when the members are exposed to the processing gas.

Also, the loading table for loading a semiconductor wafer thereon usually has a thermal resistance and a corrosion resistance in order to prevent metal contamination thereof. Therefore, at the time of manufacturing the loading table structure, a heat radiating member, such as a resistance heater, is embedded in a ceramic material, such as AlN, which is then integrally baked at a high temperature, so as to produce a loading table. Further, a support column is formed by baking a ceramic member, etc. through another process in the same manner. Then, the loading table and the support column manufactured in the way described above are integrated with each other through welding by, for example, a thermal diffusion joining. Further, the loading table structure integrated in the way as described above is attached to the bottom part within the processing container in a manner that the loading table structure stands upright. In the above process, quartz glass, which has a thermal resistance and a corrosion resistance and has a small thermal elasticity, may be used instead of the ceramic member.

Hereinafter, an example of a conventional loading table structure will be described. FIG. 16 is a sectional view of an example of a conventional loading table structure. The conventional loading table structure is installed within a processing container capable of performing vacuum discharge, and has a loading table 2 shaped like a disc, which is formed of a ceramic material, such as AlN, as shown in FIG. 16. Further, a support column 4 shaped like a cylinder, which is also formed of a ceramic material, such as MN, is joined to a central portion of a lower surface of loading table 2 through, for example, a thermal diffusion joining, so that support column 4 is integrated to loading table 2.

Therefore, support column 4 and loading table 2 are air-tightly joined with each other through a thermal diffusion joining part 6. When the wafer has a size of 300 mm, loading table 2 has a diameter of about 350 mm and support column 4 has a diameter of about 56 mm. Within loading table 2, a heating means 8 including, for example, a heater, is installed, so as to heat semiconductor wafer W, which is an object to be processed loaded on loading table 2.

The lower end of support column 4 is fixed to container bottom part 9 by a fixing block 10, so that support column 4 stands upright. Further, within cylindrical support column 4, a feeding rod 14 having an upper end connected through a connection node 12 to heating means 8 is arranged. In addition, the lower end of feeding rod 14 extends downward through an insulating member 16 at the container bottom part and is exposed to the exterior. This structure prevents the introduction of a processing gas, etc. into support column 4, thereby preventing feeding rod 14 or connection node 12 from being corroded by a corrosive processing gas.

For example, see Japanese Laid-Open Patent Publication No. sho63-278322 (Patent Document 1),

Japanese Laid-Open Patent Publication No. p07-078766 (Patent Document 2),

Japanese Laid-Open Patent Publication No. p03-220718 (Patent Document 3),

Japanese Laid-Open Patent Publication No. p06-260430 (Patent Document 4),

Japanese Laid-Open Patent Publication No. 2004-356624 (Patent Document 5), and

Japanese Laid-Open Patent Publication No. 2006-295138 (Patent Document 6).

### DISCLOSURE

### Problems to be Solved

During the processing of the semiconductor wafer, loading table 2 itself is in a high temperature state. At this time, since loading table 2 and support column 4 are joined to each other through a thermal diffusion, a large quantity of heat is radiated through support column 4 from the central portion of loading table 2 toward support column 4 even though support column 4 is formed of a ceramic material having a low heat conductivity. Therefore, especially when the temperature of loading table 2 rises or drops, the temperature of the central portion of loading table 2 becomes low, a cool spot is generated, and the temperature of the peripheral portion becomes relatively high. As a result, a big temperature difference occurs within the surface of loading table 2, thereby causing a big thermal stress between the central portion and the peripheral portion of loading table 2, which may break loading table 2.

Especially, according to the type of the process, the temperature of loading table 2 may reach above 700° C. Then, the temperature difference becomes considerably large, which thereby causes a large thermal stress. In addition, since the temperature of loading table 2 repeatedly rises and drops, the breaking of loading table 2 by the thermal stress is further promoted.

Further, at this time, the upper portions of loading table 2 and support column 4 reach a high temperature state and are thermally expanded. Meanwhile, the lower end of support column 4 is fixed to container bottom part 9 through fixing block 10. As a result, the stress is concentrated on the joining part between loading table 2 and support column 4, so that the joining part may be broken.

In order to solve this problem, instead of integrally joining loading table 2 and support column 4 through a thermal diffusion joining, a metal seal member having a high temperature thermal resistance may be interposed between loading table 2 and support column 4, which are then weakly coupled by a pin or bolt formed of a ceramic material or quartz.

In this case, a small gap is formed in the joining portion. Therefore, in order to prevent a corrosive process gas from being introduced through the small gap into support column 4, an inert gas, such as N₂ gas, Ar gas, or He gas, is supplied as a purge gas into support column 4. In this structure, since loading table 2 and the upper end of support column 4 are not tightly connected to each other, a relatively small quantity of heat is radiated toward the support column from the central portion of the loading table. As a result, it is possible to reduce the temperature difference between the central portion and the peripheral portion of loading table 2, so as to prevent application of a large thermal stress between them.

However, in this case, it is difficult to prevent the purge gas supplied into support column 4 from leaking through the small gap toward the processing space within the processing container. As a result, it is difficult to perform the process under a high vacuum state. Moreover, since a large quantity of purge gas is consumed, a high operation cost is also required.

The present invention has been made in view of and in order to solve the problems described above. Therefore, the present invention provides a loading table structure and a processing device, which can prevent the occurrence of a large thermal stress on the loading table to thereby prevent the breaking of the loading table and can reduce the quantity of corrosion-preventing purge gas supplied into a protective support column.

### Technical Solution

According to the present invention as disclosed in claim 1, there is provided a loading table structure for loading an object to be processed, the loading table structure being installed in a processing container capable of discharging a gas within the processing container, the loading table structure including: a loading table to load the object on the loading table, the loading table being formed of a dielectric material; a heating means to heat the object loaded on the loading table, the heating means being installed at the loading table; a plurality of protective support column tubes standing upright on a bottom portion of the processing container, each of the protective support column tubes having an upper end attached to a lower surface of the loading table, the protective support column tubes supporting the loading table and being formed of a dielectric material; and a functional rod member inserted and extending to the loading table through said each of the protective support column tubes.

As described above, for example, a plurality of protective support column tubes, through each of which a feeding rod, etc. is inserted, stand upright on a bottom portion of a processing container, and a loading table for loading an object to be processed is supported by the protective support column tubes. Therefore, in comparison with the conventional support column, it is possible to reduce the contact area between the loading table and the protective support column tubes and reduce the heat radiated from the loading table to the protective support column tubes, thereby preventing the occurrence of a cool spot. Therefore, it is possible to prevent the occurrence of a large thermal stress, thereby preventing the breaking of the loading table. In addition, it is possible to reduce the quantity of the corrosion preventing purge gas supplied into the protective support column tubes.

In this case, as described in claim 2, the protective support column tubes are attached to a central portion of the loading table.

As described in claim 3, one or more functional rod members are accommodated in each of the protective support column tubes.

As described in claim 4, the functional rod member may be a heater feeding rod electrically connected to the heating means.

Also, as described in claim 5, a chuck electrode for electro-statically chucking the object loaded on the loading table is provided at the loading table, and the functional rod member is a chuck feeding rod electrically connected to the chuck electrode.

As described in claim 6, a high frequency electrode for applying a high frequency electric power to the object loaded on the loading table is provided at the loading table, and the functional rod member is a high frequency feeding rod electrically connected to the high frequency electrode.

As described in claim 7, a multi-use electrode for electro-statically chucking the object loaded on the loading table and applying a high frequency electric power to the object loaded on the loading table is provided at the loading table, and the functional rod member is a multi-use feeding rod electrically connected to the multi-use electrode.

As described in claim 8, the functional rod member may be a thermocouple for measuring a temperature of the loading table.

As described in claim 9, the loading table may include a loading table body and a thermal diffusion plate, which is installed at an upper surface of the loading table body and may be formed of an opaque dielectric material different from a dielectric material forming the loading table body, while the heating means is installed within the loading table body, and an attachment plate shaped like a metal plate is embedded in the thermal diffusion plate and a distal end of the thermocouple is brazed to the attachment plate.

As described in claim 10, a connection hole, through which the thermocouple is inserted, is formed at a lower surface of the thermal diffusion plate.

As described in claim 11, the loading table may include a loading table body and a thermal diffusion plate, which is installed at an upper surface of the loading table body and may be formed of an opaque dielectric material different from a dielectric material forming the loading table body, while the heating means is installed within the loading table body and an attachment plate shaped like a metal plate is embedded in the thermal diffusion plate, a metal auxiliary heat conductive member protruding downward beyond a lower surface of the thermal diffusion plate is brazed to the lower surface of the thermal diffusion plate, and a distal end of the thermocouple is brazed to the metal auxiliary heat conductive member.

As described in claim 12, a thermocouple hole, in which a distal end of the thermocouple is inserted, is formed at the auxiliary heat conductive member.

As described in claim 13, a connection hole, in which the auxiliary heat conductive member is inserted, is formed at a lower surface of the thermal diffusion plate.

As described in claim 14, the distal end of the thermocouple is in forced contact with the auxiliary heat conductive member by a biasing force.

As described in claim 15, the functional rod member is an optical fiber connected to a radiation thermometer to measure a temperature of the loading table.

As described in claim 16, the loading table may include a loading table body and a thermal diffusion plate, which is installed at an upper surface of the loading table body and may be formed of an opaque dielectric material different from a dielectric material forming the loading table body, while the heating means is installed within the loading table body.

As described in claim 17, one of a chuck electrode for electro-statically chucking the object loaded on the loading table body of the loading table, a high frequency electrode for applying a high frequency electric power to the object, and a multi-use electrode for electro-statically chucking the object and applying a high frequency electric power to the object are installed within the thermal diffusion plate.

As described in claim 18, the loading table body is formed of quartz, the thermal diffusion plate is formed of a ceramic material, and a protection plate formed of a ceramic material is provided on a surface of the loading table body.

As described in claim 19, the loading table body and the thermal diffusion plate are integrally assembled with each other by an assembling member formed of a ceramic material.

As described in claim 20, an inert gas is supplied to a portion between the loading table body and the thermal diffusion plate.

As described in claim 21, dielectric material may be quartz or ceramic.

As described in claim 22, the loading table and the protective support column tubes are formed of an identical dielectric material.

As described in claim 23, an inert gas is supplied into the protective support column tubes.

As described in claim 24, an inert gas is filled in the protective support column tube while lower ends of the protective support column tubes are sealed.

As described in claim 25, pin inserting through-holes, through which push-up pins for moving the object upward and downward are inserted, are formed through the loading table, a pin inserting through-hole purge gas supplying means having a pin inserting through-hole gas passage for supplying a pin inserting through-hole purge gas to the pin inserting through-holes from outside of the processing container is connected to the pin inserting through-holes, and the protective support column tubes serve as a part of the pin inserting through-hole gas passage, so as to allow the pin inserting through-hole purge gas having been supplied from the outside of the processing container to flow through the protective support column tubes.

As described in claim 26, the loading table includes a loading table body and a thermal diffusion plate, which is installed at an upper surface of the loading table body and is formed of an opaque dielectric material different from a dielectric material forming the loading table body, the loading table body and the thermal diffusion plate are detachably assembled with each other by loading table bolts formed of ceramic, and the pin inserting through-holes longitudinally extend through the loading table bolts, respectively.

As described in claim 27, each of the loading table bolts has a gas injection hole for interconnecting the pin inserting through-holes and the pin inserting through-hole gas passage.

As described in claim 28, the gas injection hole is formed at a position higher than a longitudinal center of the support table bolt.

As described in claim 29, body-side bolt holes, through which the loading table bolts are inserted, are formed through the loading table body, and an around-bolt gap, through which the pin inserting through-hole purge gas passes, is formed between the support table bolt and the body-side bolt hole.

As described in claim 30, the pin inserting through-hole gas passage is formed between the loading table body and the thermal diffusion plate, and has a gas storage space for temporarily storing the pin inserting through-hole purge gas.

According to the present invention as disclosed in claim 31, there is provided a device for processing an object to be processed, the device including: a processing container capable of discharging a gas in the processing container; a loading table structure to load the object on the loading table structure, the loading table structure being installed within the processing container; and a gas supplying means for supplying the gas into the processing container, wherein the loading table structure includes: a loading table to load the object on the loading table, the loading table being formed of a dielectric material; a heating means to heat the object loaded on the loading table, the heating means being installed at the loading table; a plurality of protective support column tubes standing upright on a bottom portion of the processing container, each of the protective support column tubes having an upper end attached to a lower surface of the loading table, the protective support column tubes supporting the loading table and being formed of a dielectric material; and a functional rod member inserted and extending to the loading table through said each of the protective support column tubes.

### Effects of the Invention

A loading table structure and a processing device according to the present invention have excellent effects as follows.

For example, a plurality of protective support column tubes, through each of which a feeding rod, etc. are inserted, stand upright on a bottom portion of a processing container, and a loading table for loading an object to be processed is supported by the protective support column tubes. Therefore, in comparison with the conventional support column, it is possible to reduce the contact area between the loading table and the protective support column tubes and reduce the heat radiated from the loading table to the protective support column tubes, thereby preventing the occurrence of a cool spot. Therefore, it is possible to prevent the occurrence of a large thermal stress, thereby the preventing breaking of the loading table. In addition, it is possible to reduce the quantity of the corrosion preventing purge gas supplied into the protective support column tubes.

### BRIEF DESCRIPTION OF THE DRAWINGS

FIG. 1 is a cross sectional view of a processing device having a loading table structure according to the present invention.

FIG. 2 is a plan view illustrating a heating means of a loading table as an exemplary embodiment.

FIG. 3 is a cross sectional view taken along line A-A in FIG. 1 and viewed along the arrow direction.

FIG. 4 is a partially enlarged cross sectional view illustrating a part of protective support column tubes in the loading table structure shown in FIG. 1.

FIG. 5 is a view for describing a process of assembling the loading table structure shown in FIG. 4.

FIG. 6 is a cross sectional view illustrating a part of a loading table structure according to a modified embodiment of the present invention.

FIGS. 7 (A) and (B) illustrates partially enlarged sectional views illustrating an attachment structure of a thermocouple in a loading table.

FIGS. 8 (A), (B), (C), and (D) illustrates sectional views for describing a process of attaching thermocouples to a loading table.

FIG. 9 is a flowchart illustrating a process of attaching a thermocouple to a loading table.

FIG. 10 is a sectional view illustrating an attachment structure of a thermocouple according to the modified embodiment of the present invention.

FIG. 11 is a cross sectional view illustrating a second modified embodiment of a loading table structure.

FIG. 12 is a sectional view for describing an assembled state of the second modified embodiment.

FIG. 13 is a plan view illustrating a top surface of a loading table body of the second modified embodiment.

FIG. 14 is a cross sectional view of the third modified embodiment of the loading table structure.

FIG. 15 is a cross sectional view of the fourth modified embodiment of the loading table structure.

FIG. 16 is a cross sectional view illustrating an example of a conventional loading table structure.

### BEST MODE

Hereinafter, a loading table structure and a processing device according to an exemplary embodiment of the present invention will be described in detail with reference to the accompanying drawings.

The following description deals with an example in which a film is formed by using plasma. In the following description, a “functional rod member” refers to not only a single metal rod but also a rod-shaped member formed by coating a flexible wire or wires with an insulating material.

As shown, a processing device 20 includes a processing container 22 formed of aluminum, which has a substantially circular sectional shape. At the ceiling within processing container 22, a shower head part 24, which is a gas supplying means for introducing, for example, a film formation gas, is installed via an insulating layer 26. Further, a plurality of processing gas injection pores 32A and 32B for injecting the processing gas toward processing space S are formed at a gas injection surface 28 of the lower surface of shower head part 24. Further, shower head part 24 serves as an upper electrode at the time of plasma processing.

Within shower head part 24, two partitioned gas diffusion chambers 30A and 30B are formed. The processing gas having been introduced into gas diffusion chambers 30A and 30B are first diffused in the horizontal direction and are then injected through processing gas injection pores 32A and 32B interconnected to gas diffusion chambers 30A and 30B, respectively. Processing gas injection pores 32A and 32B are arranged in a shape of a matrix. Shower head part 24 is generally formed of nickel, nickel alloy such as Hastelloy™, aluminum, or aluminum alloy. Further, only one gas diffusion chamber may be formed within shower head part 24.

Further, a sealing member 34, such as an O-ring, is interposed in the joining part between shower head part 24 and insulating layer 26 at the open upper end of processing container 22, so as to maintain the air tightness within processing container 22. Further, a high frequency electric power source 38 of, for example, 13.56 MHz is connected to shower head part 24 through a matching circuit 36, so as to generate plasma when necessary. The frequency of high frequency electric power source 38 is not limited to 13.56 MHz.

Further, a loading/unloading port 40 for loading or unloading a semiconductor wafer to be processed into or out of processing container 22 is formed at a side wall of processing container 22, and a gate valve 42 for opening or air-tightly closing loading/unloading port 40 is arranged at loading/unloading port 40.

Moreover, a gas discharge port 46 is formed at a side portion of bottom portion 44 of processing container 22. A gas discharge system 48 for discharging the gas within processing container 22, for example, for vacuum gas discharge, is connected to gas discharge port 46. Gas discharge system 48 has a gas discharge path 49 connected to gas discharge port 46, and a pressure control valve 50 and a vacuum pump 52 are installed at gas discharge path 49, so that they can maintain the inner space of processing container 22 at a desired pressure. According to an embodiment of the present invention, the inner space of processing container 22 may be maintained at a pressure similar to the atmospheric pressure.

Further, a loading table structure 54, which corresponds to an important characteristic of the present invention, is installed at bottom portion 44 within processing container 22 capable of processing the internal gas. Specifically, loading table structure 54 includes a loading table 58 for loading an object to be processed on an upper surface thereof, a heating means 64 provided at loading table 58 to heat a wafer W loaded on loading table 58, and a plurality of relatively thin protective support column tubes 60, which stand upright on bottom portion 44 of processing container 22, have upper ends attached to the lower surface of loading table 58, and support loading table 58.

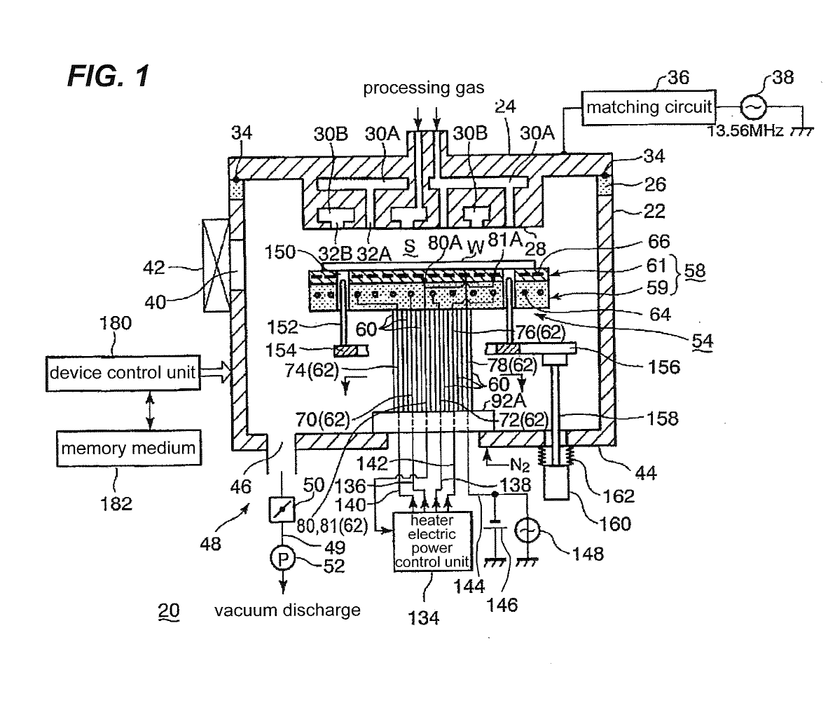

In FIG. 1, for better understanding of the invention, protective support column tubes 60 are arranged in the transverse direction. Loading table 58 shown in FIG. 1 is generally formed of a dielectric material, and includes a loading table body 59 formed of a relatively thick transparent quartz, and a heat diffusion plate 61, which is disposed on an upper surface of loading table body 59 and is formed of an opaque dielectric material different from that of loading table body 59, for example, a ceramic material, such as aluminum nitride MN, which is a heat-resistant material.

Further, heating means 64 is embedded in loading table body 59, and a multi-use electrode 66 is embedded in heat diffusion plate 61. By this structure, a wafer W loaded on the upper surface of heat diffusion plate 61 is heated by the heat from heating means 64 through heat diffusion plate 61.

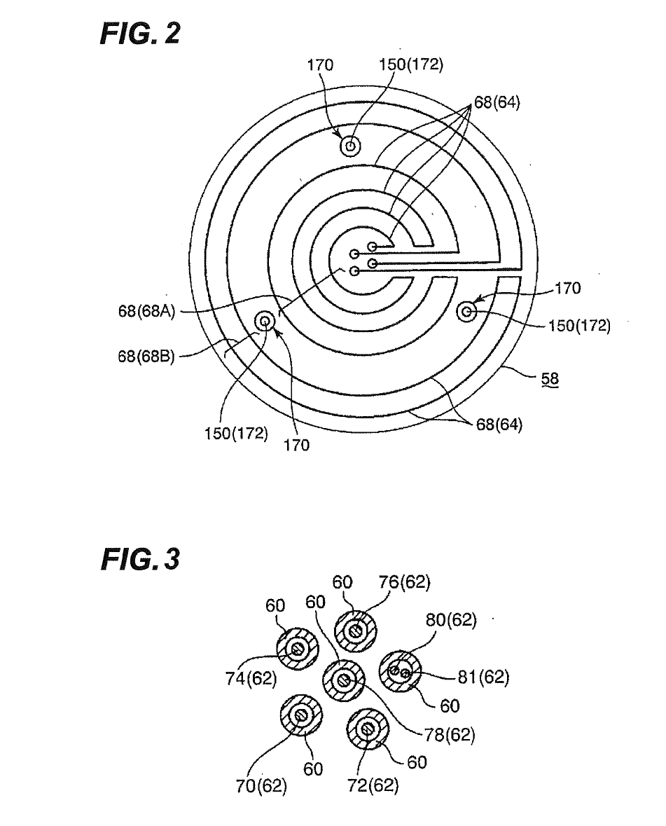

As shown in FIG. 2, heating means 64 has a heat radiating body 68 formed in a predetermined pattern over the entire surface of loading table 58. Heat radiating body 68 is formed of, for example, a carbon wire heater or a molybdenum wire heater. Further, heat radiating body 68 includes an inner peripheral zone heat radiating body 68A disposed at an inner peripheral zone of loading table 58 and an outer peripheral zone heat radiating body 68B disposed at an outer peripheral zone of loading table 58. Therefore, loading table 58 has two electrically separated zones, which include the inner peripheral zone corresponding to inner peripheral zone heat radiating body 68A and the outer peripheral zone corresponding to outer peripheral zone heat radiating body 68B. Further, connection nodes of zone heat radiating bodies 68A and 68B are collectively arranged at the central part of loading table 58. Further, heat radiating body 68 may either include only one body corresponding to a single zone or three or more sub-bodies corresponding to three or more zones.

Further, multi-use electrode 66 installed within the opaque heat diffusion plate 61 is used both as a chuck electrode for electro-statically chucking wafer W loaded on loading table 58 and as a high frequency electrode configuring a lower electrode for applying a high frequency electric power to wafer W loaded on loading table 58. Multi-use electrode 66 includes a conductive wire having a shape of a mesh and has a connection node located at the central portion of loading table 58.

In addition, a functional rod member 62 is inserted in each of protective support column tubes 60 and extends through protective support column tube 60 up to loading table 58. Functional rod members 62 include a feeding rod for feeding electricity to heat radiating body 68 or multi-use electrode 66 and a conductive rod of a thermocouple for measuring the temperature.

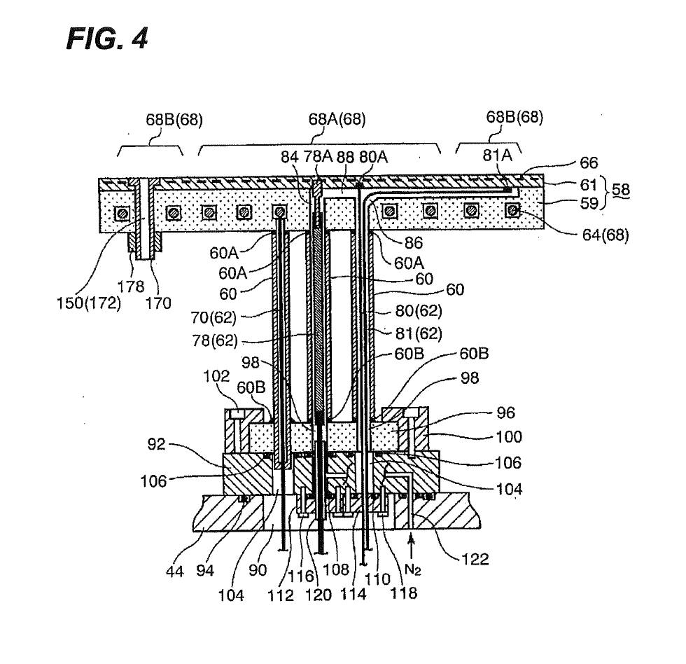

In the present embodiment, six protective support column tubes 60 are collectively arranged at the central portion of loading table 58 as shown in FIGS. 1 to 3. Each of protective support column tubes 60 is formed of a dielectric material, specifically formed of quartz, and has an upper end attached to the lower of loading table body 59 air-tightly and integrally through, for example, a thermal fusion. Therefore, a heat fusion connection part 60A is formed at the upper end of each of protective support column tubes 60 (see FIG. 4). In addition, a functional rod member 62 is inserted in and extends through each of protective support column tubes 60. FIG. 4 shows only a part of protective support column tubes 60 as representatives, and one or more functional rod members 62 (two functional rod members in the present embodiment) are inserted in each of protective support column tubes 60 as described later.

That is, as shown in FIG. 1, heater feeding rods 70 and 72, which are two functional rod members 62 for power-in and power-out of inner peripheral zone heat radiating body 68A, are inserted through protective support column tubes 60, respectively, and upper ends of heater feeding rods 70 and 72 are electrically connected to inner peripheral zone heat radiating body 68A.

Further, heater feeding rods 74 and 76, which are two functional rod members 62 for power-in and power-out of outer peripheral zone heat radiating body 68B, are inserted through protective support column tubes 60, respectively, and upper ends of heater feeding rods 74 and 76 are electrically connected to outer peripheral zone heat radiating body 68B. Also, each of heater feeding rods 70, 72. 74, and 76 is formed of, for example, nickel alloy.

Moreover, a multi-use feeding rod 78, which is a functional rod member 62 for multi-use electrode 66, is inserted through protective support column tube 60, and has an upper end electrically connected to multi-use electrode 66 through a connection node 78A (see FIG. 4). Further, multi-use feeding rod 78 is formed of, for example, nickel alloy, tungsten alloy, or molybdenum alloy.

In addition, two thermocouples 80 and 81, which are functional rod members 62 for measuring the temperature of loading table 58, are inserted through remaining protective support column tube 60. Further, these thermocouples 80 and 81 have temperature measuring contact points 80A and 81A formed at the ends thereof, respectively, and the temperature measuring contact points 80A and 81A are disposed at locations corresponding to inner peripheral zone heat radiating body 68A and outer peripheral zone heat radiating body 68B of heat diffusion plate 61, so as to detect the temperatures of the inner peripheral and outer peripheral zones. These thermocouples 80 and 81 may be, for example, sheath-type thermocouples. Each of these sheath-type thermocouples is formed by air-tightly filling powder of an inorganic insulating material, such as high purity magnesium oxide, around thermocouple element wires inserted in a metal protection tube (sheath), has a superior insulation, superior air tightness, and superior responsiveness, and shows an excellent durability against long time continuous use in a high temperature environment or under various bad atmospheres.

Further, as shown in FIG. 4, through-holes 84 and 86, which connection node 78A and thermocouple 80 and 81 may be inserted in and extend through, are formed through loading table body 59. A groove 88, which is connected to through-holes 84 and 86 and is arranged for locating one thermocouple 81 among the thermocouples from the inner peripheral zone toward the outer peripheral zone, is formed on the upper surface of loading table body 59. FIG. 4 shows heater feeding rod 70, multi-use feeding rod 78, and two thermocouples 80 and 81 as representatives of functional rod members 62.

In addition, bottom portion 44 of processing container 22 is formed of, for example, stainless steel, and has a conductor take-out port 90 formed at a central portion thereof as shown in FIG. 4. An attachment base 92 formed of, for example, stainless steel, is air-tightly attached and fixed to the inside of conductor take-out port 90 through a seal member 94, such as an O-ring.

Further, a tube holding table 96 for holding protective support column tubes 60 is arranged on attachment base 92. Tube holding table 96 is formed of the same material of protective support column tubes 60, that is, quartz. A plurality of through-holes 98 corresponding to protective support column tubes 60 are formed on tube holding table 96. Also, the lower ends of protective support column tubes 60 are connected and fixed to the upper surface of tube holding table 96 through heat fusion, etc. As a result, heat fusion connection part 60B is formed.

At this time, protective support column tubes 60, through which heater feeding rods 70, 72, 74, and 76 are inserted, are inserted through through-holes 98 formed through tube holding table 96, the lower ends of protective support column tubes 60 are sealed, and an inert gas, such as N₂ or Ar, is filled under a vacuum atmosphere within protective support column tubes 60. Although FIG. 4 shows only one heater feeding rod 70, the other heater feeding rods 72, 74, and 76 have the same construction.

Also, a fixing jig 100 formed of, for example, stainless steel, surrounds tube holding table 96 holding the lower ends of protective support column tubes 60. Fixing jig 100 is fixed to attachment base 92 by bolts 102.

Further, through-holes 104, which correspond to and are similar to through-holes 98 of tube holding table 96, are formed through attachment base 92, so that functional rod members 62 can be inserted through through-holes 104. In addition, a seal member 106, such as an O-ring, surrounding each of through-holes 104 is disposed at the joining surface between the lower surface of tube holding table 96 and the upper surface of attachment base 92, so as to enhance the sealing of the joining portion.

Further, sealing plates 112 and 114 are attached and fixed to the lower surface of attachment base 92 through sealing members 108 and 110, each of which includes an O-ring, etc., by using bolts 116 and 118. Further, sealing plates 112 and 114 are attached to the portions corresponding to through-holes 104, through which multi-use feeding rod 78 and two thermocouples 80 and 81 are inserted. Further, multi-use feeding rod 78 and thermocouples 80 and 81 extend through sealing plates 112 and 114 while maintaining air tightness. Sealing plates 112 and 114 are formed of, for example, stainless steel, and an insulating member 120 is installed at a position around multi-use feeding rod 78, which corresponds to the through-hole of sealing plate 112 for multi-use feeding rod 78.

Further, inert gas passages 122 communicating with through-holes 104, through which multi-use feeding rods 78 are inserted, are formed at attachment base 92 and bottom portion 44 of processing container 22 in contact with attachment base 92, so that an inert gas, such as N₂, can be supplied into protective support column tubes 60, through which multi-use feeding rods 78 pass. Further, since through-holes 84 and 86 are interconnected to each other through groove 88 of loading table body 59, it is possible to employ, instead of protective support column tube 60 of multi-use feeding rod 78, a construction capable of supplying an inert gas into protective support column tubes 60, through which two thermocouples 80 and 81 pass.

Now, dimensions of the elements will be briefly described. Loading table 58 may have a diameter of about 340 mm for a wafer of 300 mm (12 inches), a diameter of about 230 mm for a wafer of 200 mm (8 inches), or a diameter of about 460 mm for a wafer of 400 mm (16 inches). Also, protective support column tube 60 may have a diameter of about 8 mm to 16 mm, and functional rod member 62 may have a diameter of about 4 mm to 6 mm.

Further, as shown in FIG. 1, thermocouples 80 and 81 are connected to a heater electric power control unit 134 having a computer, etc. In addition, wires 136, 138, 140, and 142 connected to heating means 64 through heater feeding rods 70, 72, 74, and 76 are connected to heater electric power control unit 134. By this construction, based on the temperature measured by thermocouples 80 and 81, it is possible to independently control inner peripheral zone heat radiating body 68A and outer peripheral zone heat radiating body 68B, so as to maintain wafer W at a desired temperature.

A direct current electric power source 146 for an electrostatic chuck and a high frequency electric power source 148 for applying a high frequency electric power for biasing are connected to wire 144 connected to multi-use feeding rod 78. As a result, it is possible to electro-statically suck wafer W on loading table 58 and apply a high frequency electric power as a bias to loading table 58, which serves as a lower electrode at the time of processing. Although 13.56 MHz can be used as the frequency of the high frequency electric power, the present invention is not limited to the frequency of 13.56 MHz and can employ other frequencies, such as 400 kHz.

Further, three pin inserting through-holes 150 (only two holes are shown in FIG. 1) are formed in the vertical direction through loading table 58, and push-up pins 152 for moving wafer W upward and downward are inserted through pin inserting through-holes 150 in a loose state so that push-up pins 152 can be moved upward and downward. A push-up ring 154, which has an arc shape and is formed of a ceramic, such as alumina, is provided at the lower end of each of push-up pins 152, and push-up ring 154 is connected to the lower end of each of push-up pins 152. An arm part 156 extending from push-up ring 154 is connected to a protrusion/depression rod 158 extending through bottom portion 44 of processing container 22, and protrusion/depression rod 158 is connected to an actuator 160 for moving protrusion/depression rod 158 upward or downward.

When wafer W is delivered by the construction described above, each of push-up pins 152 is extracted/inserted upward from the upper end of each of pin inserting through-holes 150. Further, an extensible bellows 162 is interposed between actuator 160 and the through-hole portion of bottom portion 44 of processing container 22 for protrusion/depression rod 158, and bellows 162 maintains the air tightness within processing container 22 when protrusion/depression rod 158 is moved upward or downward.

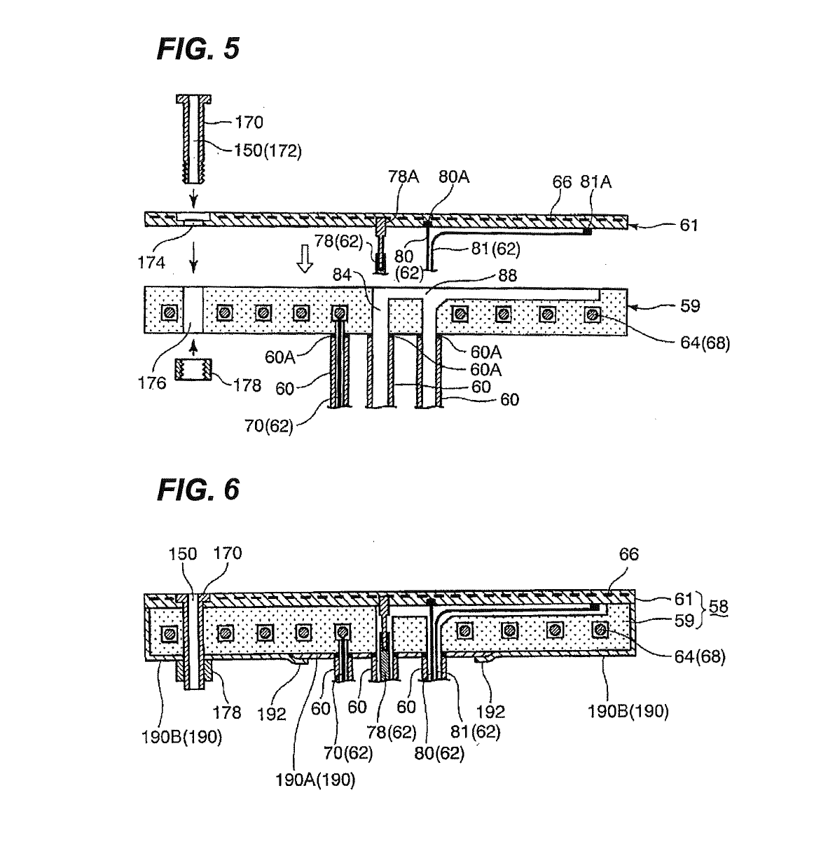

As shown in FIGS. 4 and 5, loading table body 59 and heat diffusion plate 61 are detachably assembled with each other by a bolt 170, which is an assembling member for assembling loading table body 59 and heat diffusion plate 61 together and is formed of ceramic. Pin inserting through-hole 150 is configured by a through-hole 172 longitudinally extending through bolt 170. Specifically, a plate-side bolt hole 174 and a body-side bolt hole 176, through which bolt 170 is inserted, are formed through heat diffusion plate 61 and loading table body 59, respectively. Then, bolt 170 having pin inserting through-holes 150 longitudinally extending through the bolt is inserted through plate-side bolt hole 174 and body-side bolt hole 176, and then loading table body 59 and heat diffusion plate 61 are assembled with each other by fastening bolt 170 by nut 178. Bolt 170 and nut 178 are formed of ceramic, for example, aluminum nitride or alumina.

Further, the general operation of processing device 20, including control of process pressure, temperature control of loading table 58, supply or supply interruption of the processing gas, is performed by a device control unit 180 including, for example, a computer, etc. Further, device control unit 180 has a memory medium 182 storing a computer program necessary for the operation. Memory medium 182 includes a flexible disc, a Compact Disc (CD), a hard disc, or a flash memory.

Next, an operation of processing device 20 using plasma will be described.

First, a wafer W, which has not been processed yet, is held by a carrying arm (not shown), and is then carried into processing container 22 through gate valve 42 and loading/unloading port 40, which are in an open state. Next, wafer W is delivered to elevated push-up pins 152, and elevated push-up pins 152 is lowered down, so that wafer W is loaded and supported on the upper surface of heat diffusion plate 61 of loading table 58 supported by protective support column tubes 60 of loading table structure 54. Then, direct current electric power source 146 applies a direct current to multi-use electrode 66 installed at heat diffusion plate 61 of loading table 58, so as to operate the electro-static chuck, so that wafer W is sucked and held on loading table 58. Moreover, wafer W may be held by using a clamp mechanism holding the peripheral portion of wafer W, instead of the electro-static chuck.

Next, various processing gases are supplied to shower head part 24 under flow control, and these gases are injected into processing space S from processing gas injection pores 32A and 32B. Further, through continuous operation of vacuum pump 52 of gas discharge system 48, the inner space of processing container 22 is vacuum discharged. During this process, the degree of opening of pressure control valve 50 is controlled so as to maintain the atmosphere of processing space S at a predetermined process pressure. Further, in this state, the temperature of wafer W is maintained at a predetermined process temperature. That is, a voltage is applied through heater electric power control unit 134 to inner peripheral zone heat radiating body 68A and outer peripheral zone heat radiating body 68B of heating means 64 installed at loading table 58, so as to heat inner peripheral zone heat radiating body 68A and outer peripheral zone heat radiating body 68B.

As a result, wafer W is heated and the temperature of wafer W rises by the heat from inner peripheral zone heat radiating body 68A and outer peripheral zone heat radiating body 68B. At this time, the temperatures of the wafer (loading table) of the inner peripheral zone and the outer peripheral zone are measured by temperature measuring contact points 80A and 80B of thermocouples 80 and 81 disposed at the central portion and the peripheral portion of the lower surface of heat diffusion plate 61, and the temperature of wafer W is feedback-controlled for each zone based on the measured temperatures by heater electric power control unit 134. Therefore, it is possible to control the temperature of wafer W and to maintain a high uniformity within the surface of wafer W. Further, at this time, the temperature of loading table 58 may reach about 700° C., although the temperature may be different according to the type of the process.

Further, in the case of performing a plasma processing, high frequency electric power source 38 is operated, so as to apply a high frequency electric power between shower head part 24, which is the upper electrode, and loading table 58, which is the lower electrode. Then, plasma is formed within processing space S, and a predetermined plasma processing is performed. Further, at this time, a high frequency electric power is applied from high frequency electric power source 148 to multi-use electrode 66 installed at heat diffusion plate 61 of loading table 58, so as to carry out an introduction of plasma ions.

Hereinafter, functions of loading table structure 54 will be described in detail. First, an electric power is supplied to inner peripheral zone heat radiating body 68A of the heating means through heater feeding rods 70 and 72, which are functional rod members, and an electric power is supplied to outer peripheral zone heat radiating body 68B through heater feeding rods 74 and 76. Also, the temperature of the central portion of loading table 58 is transferred to heater electric power control unit 134 through thermocouple 80, temperature measuring contact point 80A of which is in contact with the central portion of the lower surface of heat diffusion plate 61.

At this time, the temperature of the inner peripheral zone is measured by temperature measuring contact point 80A. Further, the temperature of the outer peripheral zone is measured by thermocouple 81 disposed at the outer peripheral zone. The measured temperatures are transferred to heater electric power control unit 134. Through the process as described above, the electric power supply to inner peripheral zone heat radiating body 68A and outer peripheral zone heat radiating body 68B is performed based on the feedback control.

Furthermore, a direct current voltage for the electro-static chuck and a high frequency electric power for a bias are applied to multi-use electrode 66 through multi-use feeding rod 78. Further, heater feeding rods 70, 72, 74, and 76, thermocouples 80 and 81, and multi-use feeding rod 78, which are functional rod members 62, are individually inserted through and within fine protective support column tubes 60, upper ends of which are thermally fused to the lower surface of loading table body 59 of loading table 58 in an air-tight manner (thermocouples 80 and 81 are inserted through and within a single protective support column tube 60). Further, protective support column tubes 60 stand upright on bottom portion 44 of processing container 22 and support loading table 58.

Moreover, an inert gas, such as N₂ gas, is filled in each of protective support column tubes 60, through which heater feeding rods 70, 72, 74, and 76 are inserted, and protective support column tubes 60 are then sealed in the vacuum state, so as to prevent the oxidation of heater feeding rods 70, 72, 74, and 76. In addition, the inert gas, such as N₂ gas, is supplied through inert gas passage 122 into protective support column tube 60, through which multi-use feeding rod 78 is inserted, and the N₂ gas is also supplied through groove 88 formed on the upper surface of loading table body 59 (see FIG. 4) into protective support column tube 60, through which thermocouples 80 and 81 are inserted. Furthermore, the N₂ gas is also supplied to the joining surface between loading table body 59 and heat diffusion plate 61, and is discharged in the radial direction from the peripheral portion of loading table 58 through the gap at the joining surface. As a result, it is possible to prevent the film formation gas of the processing space S from coming into the joining surface.

Further, raising and lowering of the temperature of loading table 58 are repeated in order to process wafer W. Further, when the temperature of loading table 58 reaches 700° C. as described above through the raising and lowering of the temperature of loading table 58, a thermal expansion difference by a distance of 0.2 mm to 0.3 mm occurs in the radial direction at the central portion of loading table 58 due to the thermal expansion. In the case of the conventional loading table structure also, a loading table formed of a very hard ceramic material and a support column having a relatively large diameter are strongly assembled with each other through a thermal diffusion joining. As a result, despite that the thermal expansion difference is only 0.2 mm to 0.3 mm, thermal stress repeatedly occurs due to the thermal expansion difference, so that the joining portion between the loading table and the support column may be broken.

In contrast, according to the present invention, loading table 58 is assembled with and supported by a plurality of (six in the present embodiment) relatively thin protective support column tubes 60 each having a diameter of about 1 cm. As a result, each of protective support column tubes 60 can move in response to the thermal expansion of loading table 58 in the horizontal direction and can allow the thermal expansion of loading table 58. Therefore, it is possible to prevent the application of a thermal stress to the joining portion between loading table 58 and protective support column tubes 60, thereby preventing the breaking of the upper ends of protective support column tubes 60 or the lower surface of loading table 58, that is, the joining portion between loading table 58 and protective support column tubes 60.

Further, although each of protective support column tubes 60 is strongly fixed to the lower surface of loading table 58 through thermal fusion, each of protective support column tubes 60 has a small diameter of about 10 mm as described above. As a result, it is possible to reduce the quantity of heat transferred from loading table 58 to each of protective support column tubes 60. Therefore, it is possible to reduce the heat radiated toward each of protective support column tubes 60, and it is thus possible to drastically suppress the occurrence of a cool spot in loading table 58.

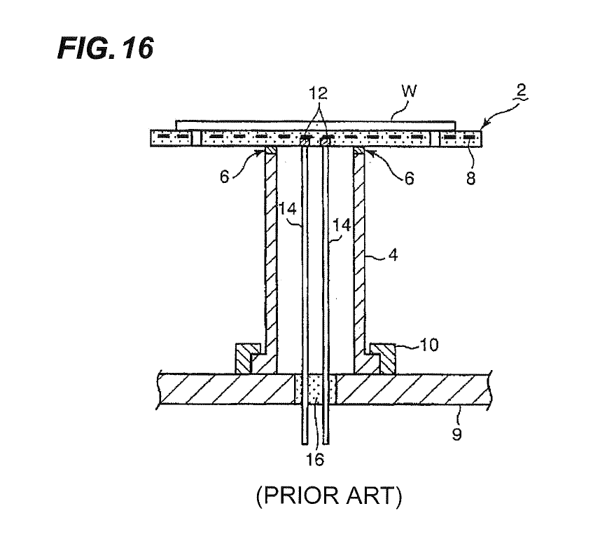

Further, functional rod members 62 are covered by protective support column tubes 60, and an inert gas is supplied as a purge gas into protective support column tubes 60 or protective support column tubes 60 are sealed with an inert gas atmosphere therein. Therefore, it is possible to prevent functional rod members 62 from being exposed to the corrosive process gas and prevent functional rod members 62 or connection node 78A from being oxidized by the inert gas. Moreover, the inert gas leaks into processing container 22 in the radial direction from the peripheral portion of loading table 58 through the gap of the joining part between loading table body 59 and heat diffusion plate 61. However, it is preferred that protective support column tubes 60 through which a purge gas flows has a size allowing multi-use feeding rod 78 to be inserted through protective support column tube. In this case, protective support column tubes 60 take a volume much smaller than that of conventional support column 4 (see FIG. 16). As a result, in comparison with the conventional loading table structure, it is possible to reduce the quantity of consumed inert gas, which can reduce the operation cost.

As described above, according to the present invention, multiple protective support column tubes 60, which heater feeding rods 70, 72, 74, and 76 are inserted in and extend through, stand upright on the bottom part of processing container 22, and loading table 58 for loading wafer W to be processed thereon is supported by protective support column tubes 60. Therefore, in comparison with the conventional support column, the present invention can reduce the area of the joining portion between loading table 58 and protective support column tubes 60, and can reduce the heat radiated from loading table 58 to protective support column tubes 60, thereby preventing the occurrence of a cool spot. As a result, the present invention can prevent the occurrence of a big thermal stress, which may break the loading table itself. Moreover, the present invention can reduce the quantity of a purge gas for preventing corrosion, which is supplied into protective support column tubes 60.

### Modified Embodiment

However, in processing device 20 described above, when a certain number of wafer sheets are subjected to a film formation processing, an unnecessary film, which may generate particles, may be attached within processing container 22. In order to remove the unnecessary film, a cleaning is performed by using an etching gas also working as a cleaning gas, such as NF₃ gas. At this time, the etching gas shows a considerably large corrosiveness with respect to quartz, in comparison with the ceramic material, such as aluminum nitride.

Therefore, it is preferred that quartz, which is a material of loading table 58, is protected from the cleaning gas. FIG. 6 is a sectional view illustrating a part of a loading table structure according to a modified embodiment of the present invention, which has a protection plate against the cleaning gas for the protection as described above. In FIG. 6, the same elements as those shown in FIG. 4 will be designated by the same reference numerals, and a detailed description thereof will be omitted.

As shown in FIG. 6, in the modified embodiment, a thin protection plate 190 is provided over the entire surface of loading table body 59 formed of quartz from among loading table 58. Specifically, the lower surface and the side surface of loading table body 59 are covered by protection plate 190. Protection plate 190 includes a central side protection plate 190A and a peripheral side protection plate 190B, which are separated from each other, and a peripheral portion of the central side protection plate 190A is held by a coupling step portion 192 formed at an inner peripheral portion of the peripheral side protection plate 190B.

Further, peripheral side protection plate 190B is attached to and fixed by support table bolt 170 and nut 178, which connect loading table body 59 and heat diffusion plate 61 with each other. Protection plate 190 may be formed of a thin ceramic material having a good corrosion resistance against the etching gas, such as aluminum nitride or alumina. In this structure, the alumina, etc. has a low heat conductivity and may be broken by itself when there is a temperature difference. In order to prevent this breaking, it is preferred to make the boundaries of central side protection plate 190A and peripheral side protection plate 190B coincide with inner peripheral zone heat radiating body 68A and outer peripheral zone heat radiating body 68B. This is because it is often the case that a temperature difference occurs between inner peripheral zone heat radiating body 68A and outer peripheral zone heat radiating body 68B. According to the modified embodiment of the present invention as described above, it is possible to protect the quartz part of loading table 58 from corrosion by an etching gas.

### <Structure of Joining Part of Thermocouple>

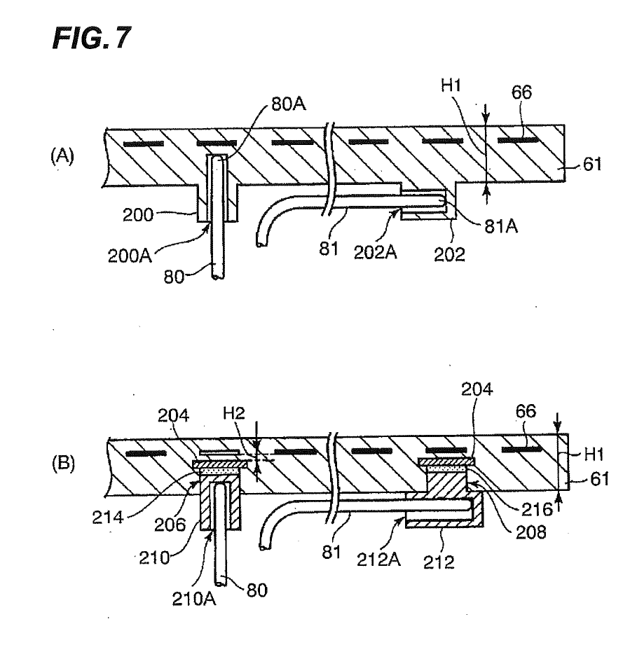

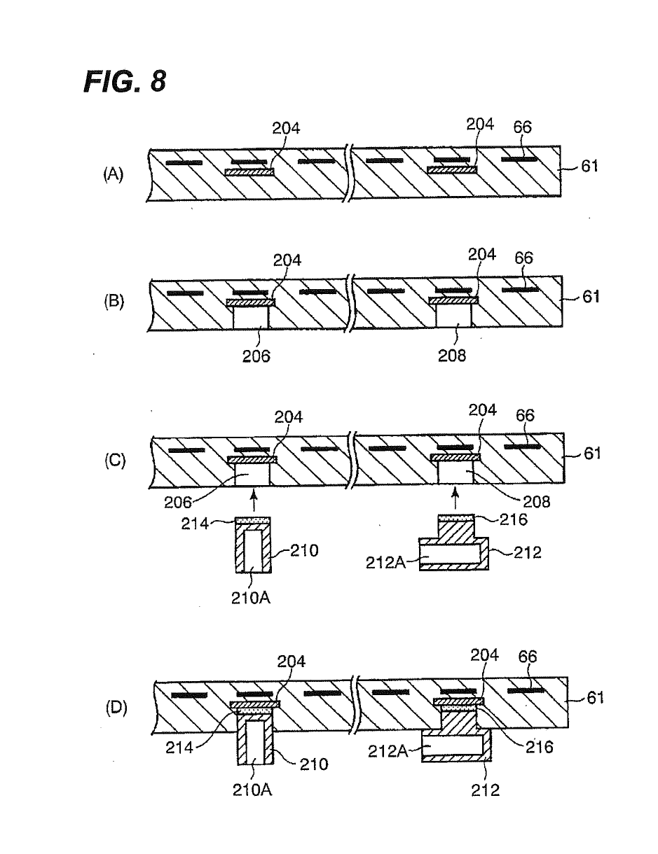

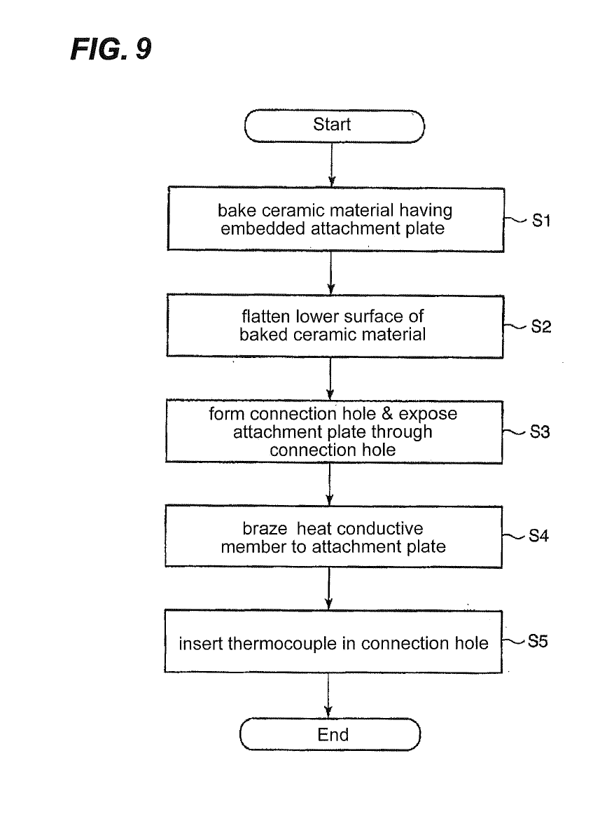

Next, an attachment structure of a thermocouple to a loading table of a loading table structure will be discussed. FIGS. 7A and 7B are partially enlarged sectional views illustrating an attachment structure of a thermocouple in a loading table, wherein FIG. 7A illustrates a first example of the attachment structure of the present invention and FIG. 7B illustrates a second example of the attachment structure of the present invention. FIGS. 8A to 8D are sectional views for describing a process of attaching thermocouples to a loading table, and FIG. 9 is a flowchart illustrating a process of attaching a thermocouple to a loading table. In FIGS. 7A to 9, the same elements as those shown in FIGS. 1 to 6 will be designated by the same reference numerals, and a detailed description thereof will be omitted.

As shown in FIGS. 1 to 5 described above, loading table 58 of a loading table structure according to the present invention includes a loading table body 59 formed of quartz, and a heat diffusion plate 61, which is disposed on loading table body 59, is shaped like a thin plate, and is formed of a ceramic material, such as aluminum nitride AlN. Further, a thermocouple 80 for detecting the temperature of the inner peripheral zone and a thermocouple 81 for detecting the temperature of the outer peripheral zone are attached to heat diffusion plate 61 formed of the ceramic material.

In the attachment structure of thermocouples 80 and 81, a thick ceramic material, such as AlN, within which a multi-use electrode 66 is embedded, is first baked. Then, a lower surface of the baked ceramic material is cut out, so that the entire thickness of the ceramic material is reduced while protuberances 200 and 202 for attaching thermocouples 80 and 81 are formed in the inner peripheral zone and the outer peripheral zone as in the first example shown in FIG. 7A.

At this time, the ceramic material has a thickness (H1) of about 5 mm to 7 mm. Further, an attachment hole 200A is formed in protuberance 200 of the inner peripheral zone and extends upward from the lower end of protuberance 200, and an attachment hole 202A extending in the horizontal direction is formed in protuberance 202 of the outer peripheral zone, so that thermocouples 80 and 81 are inserted in and attached to attachment holes 200A and 202A, respectively. At this time, in order to measure the temperature of wafer W more exactly, attachment hole 200A of the inner peripheral zone is formed deeply so that the end of thermocouple 80 approaches to wafer W as close as possible.

The reason of thickness reduction of heat diffusion plate 61 is in order to effectively heat wafer W by the heat radiated from heat radiating body 68 (see FIG. 4) of loading table body 59 located under heat diffusion plate 61. At this time, if the depth of attachment holes 200A and 202A is too shallow, the radiation heat may be directly introduced into attachment holes 200A and 202A from heat radiating body 68 located under attachment holes 200A and 202A, which may cause a thermally external disturbance having a bad influence on the wafer, thereby making it impossible to measure an exact temperature of wafer W. However, as described above, protuberances 200 and 202 arranged for the attachment of thermocouples 80 and 81 make it possible to secure a sufficient depth for each of attachment holes 200A and 202A, to prevent the application of the bad influence by the thermally external disturbance, and to measure an exact temperature of wafer W.

When protuberances 200 and 202 are also formed of the ceramic material, which is the same material as that of heat diffusion plate 61, and are integrally formed with heat diffusion plate 61, protuberances 200 and 202 are prone to receive the radiation heat from the heating body located under them. As a result, the radiation heat received from protuberances 200 and 202 is easily transferred to the heat diffusion plate integrally formed through the cut-out work. This heat may cause the temperature of the portions, at which protuberances 200 and 202 are arranged, to be different from that of the surroundings, thereby degrading the temperature uniformity within the surface of wafer W.

Further, since protuberances 200 and 202 are formed by cutting out the lower surface of a thick hard plate-shaped ceramic material, the cut-out job requires a highly increased working cost, which increases the entire expense. Therefore, in the second example of the attachment structure, the protuberances are formed of a material (metal), which is different from that of the heat diffusion plate. That is, as shown in FIG. 7B, in the second example of the attachment structure of thermocouples 80 and 81 in heat diffusion plate 61 of the loading table structure according to the present invention, a metal attachment plate 204 having a shape of a plate is embedded in a portion to which thermocouples 80 and 81 are attached.

In order to measure the temperature of the wafer more exactly, attachment plate 204 is disposed as near as possible to the loading surface, which is the upper surface. However, attachment plate 204 should be insulated from multi-use electrode 66 embedded in the heat diffusion plate. Therefore, attachment plate 204 is located slightly under multi-use electrode 66, and a lower limit to the distance H2 between multi-use electrode 66 and attachment plate 204 is, for example, about 1 mm. Further, attachment plate 204 has a thickness of, for example, about 0.1 mm to 1.0 mm, and heat diffusion plate 61 has a thickness H1 of about 5 mm to 7 mm as in the case of FIG. 7A.

Attachment plate 204 may be formed of a metal, which has a good thermal conductivity and does not easily undergo a metal contamination, for example, Kovar™. Further, connection holes 206 and 208 are formed under attachment plate 204, and metal auxiliary heat conductive members 210 and 212 are inserted in connection holes 206 and 208, respectively, and upper ends of auxiliary heat conductive members 210 and 212 are brazed to attachment plate 204, respectively, by brazing materials 214 and 216 including, for example, gold lead. Auxiliary heat conductive members 210 and 212 may be formed of a metal, which has a good thermal conductivity and is hard to undergo a metal contamination, for example, Kovar™.

The lower ends of auxiliary heat conductive members 210 and 212 protrude lower than the lower surface of heat diffusion plate 61, and auxiliary heat conductive member 210 of the inner peripheral zone among them has a shape of a vertically extending cylinder. Further, auxiliary heat conductive member 212 of the outer peripheral zone includes a vertically extending cylindrical part, which is inserted in connection hole 208, and a downward extending protuberance part, which extends in the radial direction of heat diffusion plate 61 shaped like a disc and has a semi-circular sectional shape.

Further, a thermocouple hole 210A, which vertically extends and has an open lower end, is formed at auxiliary heat conductive member 210 of the inner peripheral zone. Further, thermocouple 80 is inserted upward into thermocouple hole 210A from under thermocouple hole 210A, and the upper end (distal end) of thermocouple 80 is in contact with the bottom (upper end) of thermocouple hole 210A. In this state, a spring (not shown) is installed under thermocouple 80, so that the biasing force of the spring causes thermocouple 80 to be in tight contact with the bottom of thermocouple hole 210A while being pushed upward, thereby making the thermal resistance be as small as possible.

Also, a thermocouple hole 212A, which is open toward the center of heat diffusion plate 61 and extends in the central direction (horizontal direction), is formed at auxiliary heat conductive member 212 of the outer peripheral zone. Moreover, thermocouple 81 is inserted into thermocouple hole 212A in the central direction of heat diffusion plate 61, while the upper surface and the distal end of thermocouple 81 are in contact with the side surface or the bottom surface of thermocouple hole 212A. In this state, thermocouple 81 is bent in the horizontal direction from the center of heat diffusion plate 61, and thermocouple 81 is elastically bent. Therefore, the restoring force due to this elastic bending serves as a biasing force, which makes thermocouple 81 be in forced contact with the side wall of thermocouple hole 212A, thereby making the thermal resistance be as small as possible.

Next, a method of manufacturing the attachment structure of the thermocouple as described above will be described. First, as shown in FIG. 8A, a multi-use electrode 66 and two attachment plates 204 are embedded in predetermined portions of a ceramic material, such as AlN, before baking. In this state, this ceramic material is baked so that it is hardened (S1). As a result, a heat diffusion plate 61 having a flat disc-shaped lower surface is formed.

Next, the lower surface of heat diffusion plate 61 formed of a baked ceramic material shaped like a disc as described above is flattened through a weak grinding (S2). At this time, differently from the attachment structure of the first example shown in FIG. 7A, it is not necessary to perform a cut-out job in order to form protuberances 200 and 202, so that it is possible to remarkably reduce the manufacturing cost. Further, when the lower surface of the disc-shaped ceramic member has a good flatness, the grinding job is unnecessary.

Next, as shown in FIG. 8B, a hole forming process is performed from the lower surface of heat diffusion plate 61, so as to form connection holes 206 and 208 at the portions of heat diffusion plate 61 corresponding to attachment plates 204, and attachment plates 204 are exposed at the bottom portion (upper end) of connection holes 206 and 208 (S3). Next, as shown in FIG. 8C, an auxiliary heat conductive member 210, in which a thermocouple hole 210A is formed in advance, and an auxiliary heat conductive member 212, in which a thermocouple hole 212A is formed in advance, are prepared. Thereafter, as shown in FIG. 8D, these auxiliary heat conductive members 210 and 212 are inserted in connection holes 206 and 208, and the upper ends of auxiliary heat conductive members 210 and 212 are brazed to attachment plates 204 by using brazing materials 214 and 216 (S4).

Further, after auxiliary heat conductive members 210 and 212 are brazed to attachment plates 204 as described above, the distal ends of thermocouples 80 and 81 are inserted and attached in thermocouple holes 210A and 212A of auxiliary heat conductive members 210 and 212 (S5), so that the attachment of thermocouples 80 and 81 is completed as shown in FIG. 7B. Thereafter, heat diffusion plate 61 is installed on loading table body 59 (see FIG. 5). At this time, thermocouples 80 and 81 are inserted through protective support column tubes 60, respectively.

In the attachment structure of the thermocouples formed as described above, differently from the attachment structure of the first example shown in FIG. 7A, auxiliary heat conductive members 210 and 212 are formed of a material, for example, Kovar™, which is different from the material of heat diffusion plate 61, for example, AlN. Therefore, even when the heat radiated from heat radiating body 68 of loading table body 59 located under auxiliary heat conductive members 210 and 212 has been introduced into the protuberance parts of auxiliary heat conductive members 210 and 212, the introduced heat is not well-conducted toward heat diffusion plate 61, which is formed of a different kind of material. Therefore, it is possible to prevent the introduced radiation heat from having a thermally bad influence on the portions at which auxiliary heat conductive members 210 and 212 are installed. As a result, it is possible to maintain a high temperature uniformity within the surface of wafer W.

Further, for the lower surface of heat diffusion plate 61, a flattening job is sufficient when necessary. Therefore, the lower surface of heat diffusion plate 61 does not require a complicated cut-out job for forming protuberances 200 and 202 of the attachment structure of the first example shown in FIG. 7A, so that it is possible to drastically reduce the working expense.

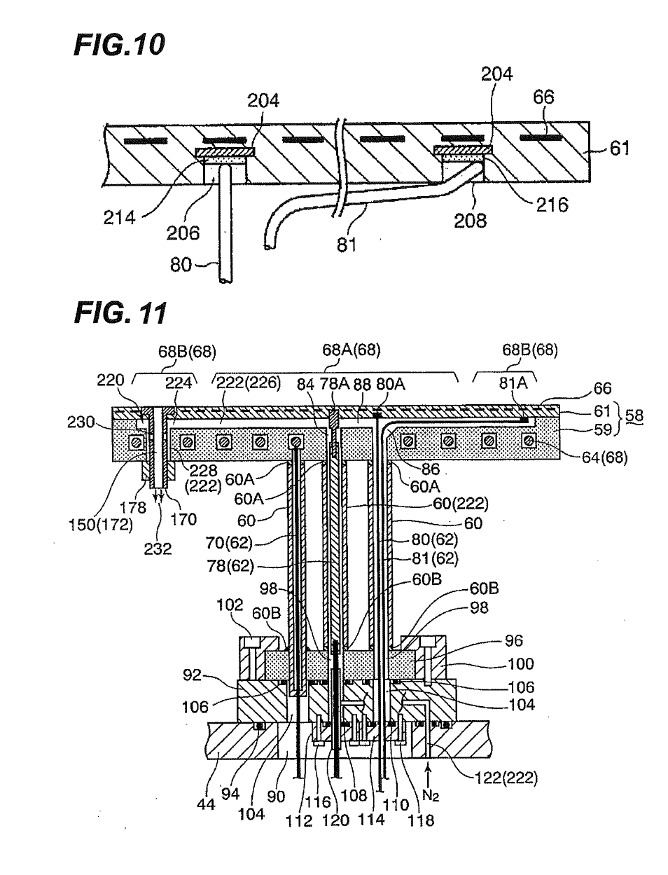

Although the attachment structure of the thermocouples also uses auxiliary heat conductive members 210 and 212, the present invention is not limited to this structure. That is, without using auxiliary heat conductive members 210 and 212, as noted from the modified embodiment of the attachment structure of the thermocouples shown in FIG. 10, it is possible to directly attach the distal ends of thermocouples 80 and 81 to attachment plates 204 exposed within connection holes 206 and 208 by brazing materials 214 and 216. In this case, in addition to the effects described above, since auxiliary heat conductive members 210 and 212 are unnecessary, it is possible to further reduce the expense.

Further, although the present embodiment described above is based on an example in which the attachment structure of the thermocouples is applied to the loading table structure having protective support column tubes 60 arranged therein, the present invention is not limited to this example, and the attachment structure of the thermocouples as described above can be applied to the conventional loading table structure using the relatively thick cylindrical support column 4 according to the prior art as shown in FIG. 16.

### 2^{nd} Modified Embodiment

In the embodiments described above, in the film formation process, the process gas flows around toward the rear side of loading table 58, and then flows into pin inserting through-holes 150 formed at support table bolt 170. In order to prevent misalignment of the location when wafer W is loaded on loading table 58, pin inserting through-hole 150 has an inner diameter of about 4 mm, push-up pin 152 has a diameter of about 3.8 mm, and a small gap is formed between pin inserting through-hole 150 and push-up pin 152. In this structure, when a processing gas for film formation has entered into pin inserting through-holes 150, thin films are gradually accumulated within the pin inserting through-holes 150 and it becomes difficult to move push-up pins 152 upward and downward. Therefore, it is necessary to perform frequent washing operations through periodic or non-periodic dry etchings or wet etchings, which degrades the throughput.

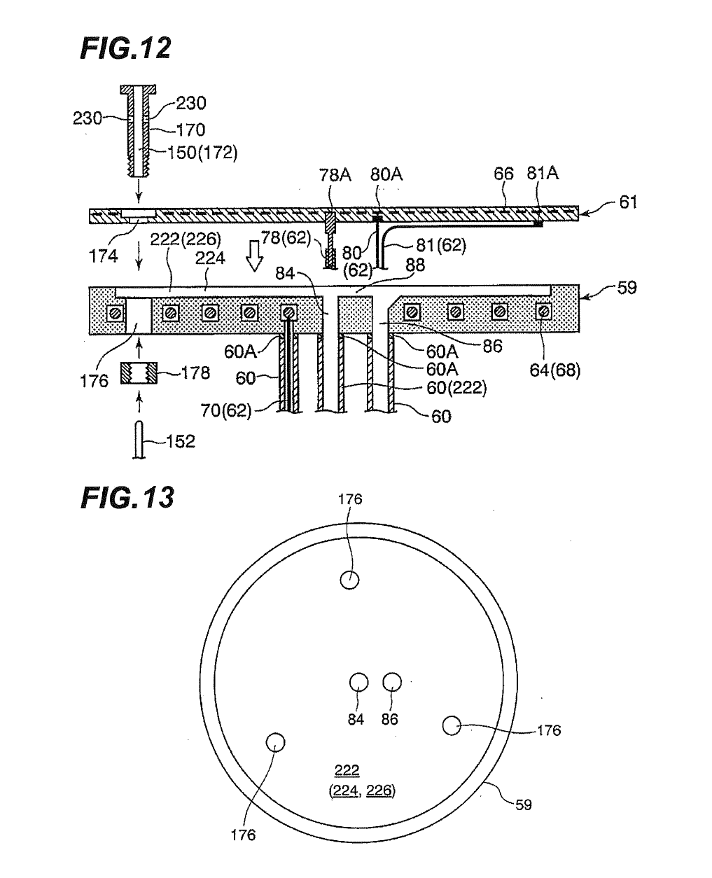

Therefore, in the second modified embodiment, a purge gas for the pin inserting through-hole is supplied into pin inserting through-holes 150, so as to prevent the accumulation of thin films within pin inserting through-holes 150. FIG. 11 is a sectional view illustrating a second modified embodiment of a loading table structure for achieving the object described above, FIG. 12 is a sectional view for describing an assembled state of the second modified embodiment, and FIG. 13 is a plan view illustrating a top surface of a loading table body of the second modified embodiment. In FIGS. 11 to 13, the same elements as those shown in FIGS. 1 to 10 will be designated by the same reference numerals, and a detailed description thereof will be omitted.

As shown in FIG. 11, a pin inserting through-hole 150 is formed in the longitudinal direction through support table bolt 170, which is a device for detachably assembling loading table body 59 and heat diffusion plate 61 with each other. Although FIG. 11 shows only one support table bolt 170, each of the other two support table bolts, which are not shown, has the same construction. Further, pin inserting through-hole 150 is connected to a pin inserting through-hole purge gas supplying means 220 for supplying a purge gas for the pin inserting through-hole to pin inserting through-holes 150 from the exterior (bottom part) of processing container 22 (see FIG. 1). Pin inserting through-hole purge gas supplying means 220 has a pin inserting through-hole gas passage 222 for introducing a pin inserting through-hole purge gas (inert gas) into processing container 22 from the bottom side of processing container 22 (see FIG. 1) and supplying the purge gas to pin inserting through-holes 150 through the interior of loading table 58, wherein N₂ gas can be supplied at the time of film formation as the inert gas.

From among the plurality of protective support column tubes 60, a protective support column tube 60, which is not sealed and instead is opened, serves as a part of pin inserting through-hole gas passage 222, so as to allow the inert gas to flow through it. That is, in FIG. 11, protective support column tube 60, through which multi-use feeding rod 78 is inserted, is also used as a part of pin inserting through-hole gas passage 222. Further, inert gas passage 122 for introducing the inert gas into protective support column tube 60 functions as a part of pin inserting through-hole gas passage 222. That is, inert gas passage 122 is also used as a part of pin inserting through-hole gas passage 222.

Further, pin inserting through-hole gas passage 222 is formed between loading table body 59 and heat diffusion plate 61, and has a gas storage space 224 for temporarily storing the inert gas. The inert gas stored in this gas storage space 224 is discharged in the radial direction from the peripheral portion of loading table 58 through a small gap formed between loading table body 59 and heat diffusion plate 61. Specifically, as shown in FIG. 13, gas storage space 224 has a circular recess 226 formed on the upper surface of loading table body 59, and circular recess 226 has a shape of a ring formed by leaving only the annular peripheral portion of the upper surface of loading table body 59. By attaching heat diffusion plate 61 on loading table body 59, gas storage space 224 is formed between the lower surface of heat diffusion plate 61 and circular recess 226.

Gas storage space 224 is interconnected through through-hole 84 to protective support column tube 60, through which multi-use feeding rod 78 is inserted. Accordingly, the inert gas introduced in gas storage space 224 from protective support column tube 60 is diffused radially outward of gas storage space 224, and is discharged radially in processing container 22 through the small gap between loading table body 59 and heat diffusion plate 61 as described above. Further, although not clearly shown in FIG. 4 or 6, gas storage space 224 is arranged also in the embodiment shown in FIG. 4 or 6. Moreover, gas storage space 224 extends radially outward beyond the location at which support table bolt 170 is disposed. As described above, gas storage space 224 serves as a part of pin inserting through-hole gas passage 222.

Further, a body-side bolt hole 176 (see FIG. 12), in which support table bolt 170 is inserted, is formed at loading table body 59. Body-side bolt hole 176 has an inner diameter, which is slightly larger than the diameter of support table bolt 170 inserted in body-side bolt hole 176. When support table bolt 170 is inserted through body-side bolt hole 176, a small around-bolt gap 228 is formed between support table bolt 170 and body-side bolt hole 176. Around-bolt gap 228 is interconnected to gas storage space 224, so that the inert gas can flow through around-bolt gap 228. That is, around-bolt gap 228 serves as a part of pin inserting through-hole gas passage 222.

Further, support table bolt 170 has a gas injection hole 230 for interconnecting pin inserting through-holes 150 and pin inserting through-hole gas passage 222 (around-bolt gap 228). As a result, the inert gas supplied to around-bolt gap 228 is injected through gas injection hole 230 into pin inserting through-hole 150. Support table bolt 170 may have either a single gas injection hole 230 or multiple gas injection holes 230. Further, it is preferred that gas injection hole 230 is formed at a position higher (at the side of heat diffusion plate 61) than the longitudinal center of support table bolt 170. Then, it is possible to effectively suppress the introduction of a processing gas for film formation into gas injection hole 230.

During a film formation process in this construction, an inert gas (for example, N₂ gas) is supplied into pin inserting through-holes 150 through pin inserting through-hole gas passage 222 of pin inserting through-hole purge gas supplying means 220. In this case, the inert gas is first supplied into the protective support column tube 60, through which multi-use feeding rod 78 is inserted, through inert gas passage 122 arranged at the bottom part of processing container 22. Thereafter, the inert gas flows upward within protective support column tube 60, and is then supplied to gas storage space 224 through through-hole 84. Then, the inert gas is supplied from gas storage space 224 to around-bolt gap 228, and is injected into pin inserting through-hole 150 through gas injection hole 230.

The inert gas having been supplied into gas storage space 224 is diffused radially outward within gas storage space 224, so that most of the inert gas is discharged into processing container 22 from the joining part between loading table body 59 and heat diffusion plate 61. However, a part of the inert gas is supplied to around-bolt gap 228 formed at the peripheral portion of support table bolt 170, and is supplied into pin inserting through-hole 150 through gas injection hole 230 from around-bolt gap 228. Further, during the film forming process, the upper ends of pin inserting through-holes 150 are blocked by the rear surface of wafer W. Therefore, the inert gas having been introduced into pin inserting through-holes 150 is continuously discharged from the lower ends of pin inserting through-holes 150 as designated by arrows 232 of FIG. 11, so as to prevent the processing gas for film formation from coming into pin inserting through-holes 150.

Through this process, it is possible to prevent the accumulation of thin films within pin inserting through-holes 150. As a result, the dry etching or wet etching for removing the thin films accumulated within pin inserting through-holes 150 either can be performed a reduced number of times or may become unnecessary. Therefore, it is possible to improve the throughput in the semiconductor wafer processing. Further, the other functions and effects are the same as those described above with reference to FIGS. 1 to 5.

### 3^{rd} Modified Embodiment

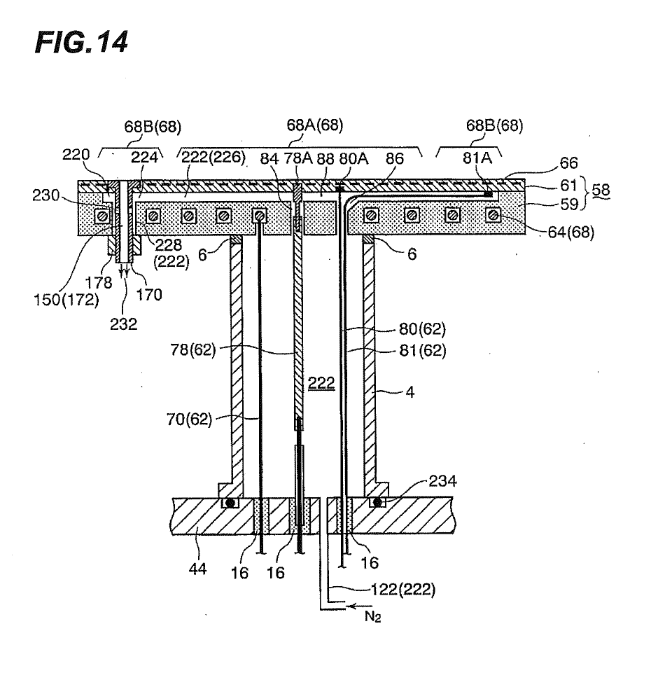

In the embodiments described above, a loading table 58 is supported by a plurality of thin protective support column tubes 60. However, the construction of pin inserting through-hole purge gas supplying means 220 according to the present invention may be applied to the conventional loading table structure also, in which a loading table 58 is supported by a thick support column having a large diameter. FIG. 14 is a sectional view of the third modified embodiment of the loading table structure. In FIG. 14, the same elements as those shown in FIGS. 1 to 13, and 16 will be designated by the same reference numerals, and a detailed description thereof will be omitted.

In FIG. 14, between loading table 58 and the bottom part of processing container 22, a support column 4, which has a large diameter and is hollow as that shown in FIG. 16, and is formed of, for example, ceramic, is installed, without any fine protective support column tube 60 at all. An upper end of support column 4 is attached to a central portion of the lower surface of loading table 58 by a thermal diffusion joining part 6, and a lower end of support column 4 is air-tightly fixed to the bottom part of processing container 22 through a seal member 234, such as an O-ring. Further, each of heater feeding rods 70 (only one heater feeding rod is shown while the others are omitted in FIG. 14), multi-use feeding rod 78, and thermocouples 80 and 81 are exposed out of the bottom part of processing container 22 after extending through insulating member 16. Further, in FIG. 14, the entire inner space of support column 4 serves as a part of pin inserting through-hole gas passage 222, so as to allow an inert gas (for example, N₂ gas) to flow through support column 4.

Therefore, the inert gas having been introduced from inert gas passage 122 flows upward through the entire inside of support column 4. Then, as described above with reference to FIG. 11, the inert gas sequentially flows through through-holes 84, gas storage space 224, and around-bolt gap 228, and is then supplied into pin inserting through-hole 150 through gas injection hole 230. This structure has effects similar to those of the second modified embodiment. Also, in the constitution where a plurality of protective support column tubes 60 are provided as shown in FIG. 11, support column 4 may be provided as shown in FIG. 14 so that the plurality of protective support column tubes 60 are inserted and penetrated.

### 4^{th} Modified Embodiment

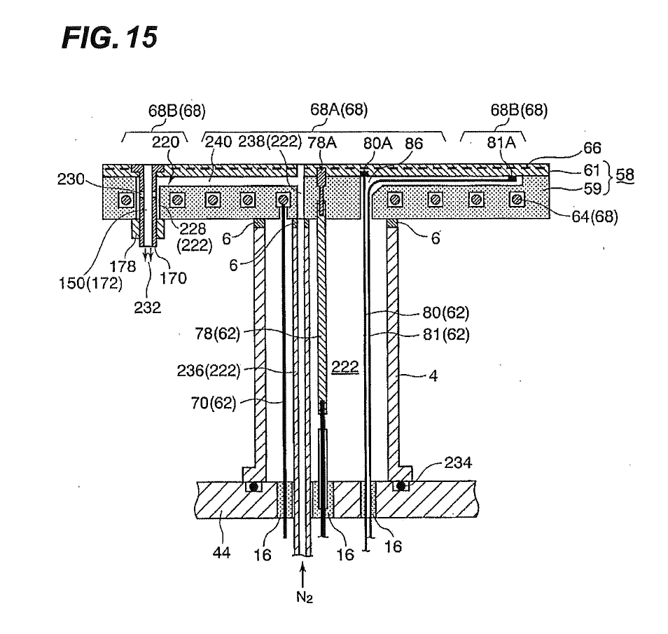

In the embodiments described above, a part of the pin inserting through-hole gas passage 222 is used also as a gas passage for supplying an inert gas to a joining surface between heat diffusion plate 61 and loading table body 59. According to another embodiment of the present invention, a part of pin inserting through-hole gas passage 222 may be used also as a gas passage for supplying an inert gas to a rear surface of wafer W. FIG. 15 is a sectional view of a loading table structure according to the fourth modified embodiment of the present invention, which uses the loading table structure shown in FIG. 14. In FIG. 15, the same elements as those shown in FIGS. 1 to 14, and 16 will be designated by the same reference numerals, and a detailed description thereof will be omitted.

First, a back side gas tube 236 extending through the bottom portion of processing container 22 is installed within thick support column 4. An upper end of back side gas tube 236 is connected to a back side through-hole 238 extending vertically through loading table 58. Through back side gas tube 236 and back side through-hole 238, an inert gas, such as N₂ gas, is supplied to the back side of wafer W. Back side gas tube 236 is attached to the lower surface of loading table body 59 through, for example, thermal diffusion joining part 6. Further, a groove 240, which extends from back side through-hole 238 to the position at which support table bolt 170 is installed, is formed at the joining surface between loading table body 59 and heat diffusion plate 61, for example, the upper surface of loading table body 59. Groove 240 serves as a part of pin inserting through-hole gas passage 222 of pin inserting through-hole purge gas supplying means 220, so as to allow the inert gas to pass through groove 240. Further, back side gas tube 236 also serves as a part of pin inserting through-hole gas passage 222, so as to allow the inert gas to pass through back side gas tube 236.

In the present embodiment, during the film formation process, most of the inert gas having been introduced into back side gas tube 236 is discharged upward from back side through-hole 238, and is then supplied to the back side of wafer W loaded on the upper surface of heat diffusion plate 61. Meanwhile, a part of the inert gas is supplied to around-bolt gap 228 through groove 240 branched off from back side through-hole 238, and is then supplied into pin inserting through-holes 150 through gas injection hole 230 arranged in support table bolt 170. Therefore, this structure described above also has effects similar to those of the embodiments described above.

Further, in the embodiments described above, a gas passage installed in advance for another use can be used also as a part of pin inserting through-hole gas passage 222. However, the present invention is not limited to this construction and allows the new installation of a separate pin inserting through-hole gas passage 222 dedicated for the purge gas to be supplied into the pin inserting through-holes.

Furthermore, in the embodiments described above, pin inserting through-hole 150 is formed through support table bolt 170. However, the present invention is not limited to this construction and allows the installation of pin inserting through-hole purge gas supplying means 220 even when loading table body 59 and heat diffusion plate 61 are integrally attached to each other through an adhesive or welding.

In addition, in the loading table structure according to the embodiments described above, loading table 58 is supported by support column 4 or a plurality of protective support column tubes 60. However, the present invention is not limited to this construction and can be applied to a loading table structure, in which a loading table is directly attached to the bottom portion of processing container 22, without support column 4 or protective support column tubes 60.

In addition, in the embodiments described above, aluminum nitride is mainly used as a ceramic material. However, the present invention is not limited to this construction and allows use of other ceramic materials, such as alumina and SiC. Also, in the embodiments described above, loading table 58 has a two layer structure including loading table body 59 and heat diffusion plate 61. However, the present invention is not limited to this construction, and entire loading table 58 may have a single layer structure formed of the same dielectric material, such as quartz or ceramic material.

When transparent quartz is used as the material of loading table 58, a uniform heat table formed of a ceramic material may be arranged on the upper surface of loading table 58, in order to prevent a pattern shape of the heat radiating body to be projected onto the rear surface of the wafer and thus cause a heat distribution thereon. Further, in the case of using an opaque quartz containing bubbles therein, the heat uniform plate is unnecessary. In addition, although N₂ gas is mainly used as the inert gas in the embodiments described above, it is possible to use a rare gas, such as He or Ar.

Also, in the embodiments described above, a multi-use electrode 66 is installed at loading table 58, and a direct current voltage for an electro-static chuck and a high frequency electric power for a bias are applied through multi-use feeding rod 78 to multi-use electrode 66. However, for the electric power supply as described above, either two separated elements or only one of them may be arranged. For example, when two separated elements are arranged, two electrodes each having a structure similar to that of multi-use electrode 66 are arranged in a vertical direction, and one electrode is used as a chuck electrode while the other electrode is used as a high frequency electrode. Moreover, a chuck feeding rod, which is a functional rod member, is electrically connected to the chuck electrode, while a high frequency feeding rod, which is also a functional rod member, is electrically connected to the high frequency electrode. Each of the chuck feeding rod and the high frequency feeding rod is inserted through protective support column tube 60, and has the same lower structure as that of the other functional rod members 62.

Also, by providing a ground electrode having the same structure as that of multi-use electrode 66, connecting functional rod member 62 working as a conductive rod to the ground electrode 66 and grounding the lower end of functional rod member 62, the ground electrode may be grounded. Further, heat radiating bodies of multiple zones may be installed, one heater feeding rod is grounded, and one heater feeding rod of each zone radiating body may be commonly used as the grounded heater feeding rod.

Further, the present embodiment has been described based on a processing device using plasma as an example. However, the present invention is not limited to this construction and can be applied to all processing devices using a loading table structure in which a heating means 64 is embedded in a loading table 58, such as a film formation device, an etching device, a thermal diffusion device, a diffusion device, or a reforming device. In this case, multi-use electrode 66 (including a chuck electrode or a high frequency electrode) or thermocouple 80 and members related to them may be omitted.

Furthermore, the gas supplying means is not limited to shower head part 24, and a gas nozzle inserted in processing container 22 may be used as the gas supplying means.

In addition, instead of employing thermocouples 80 and 81 as a temperature measuring means, a radiation thermometer may be used as the temperature measuring means. In this case, an optical fiber connected to the radiation thermometer serves as a functional rod member, through which light from the radiation thermometer passes, and the optical fiber is inserted through protective support column tube 60.

Further, an object to be processed is a semiconductor wafer in the embodiments described above. However, the present invention is not limited to this construction and can be applied to a glass substrate, an LCD substrate, a ceramic substrate, etc.

1. A loading table structure for loading an object to be processed, the loading table structure being installed in a processing container capable of discharging a gas within the processing container, the loading table structure comprising:
a loading table configured to load the object to be processed, the loading table being formed of a dielectric material;
a heating means to heat the object to be processed loaded on the loading table, the heating means being installed at the loading table;
a plurality of protective support column tubes standing upright on a bottom portion of the processing container, each of the protective support column tubes having an upper end attached to a lower surface of the loading table, the protective support column tubes supporting the loading table and being formed of a dielectric material; and
a functional rod member inserted into and penetrate said each of the protective support column tubes, and extending to the loading table.

2. The loading table structure as claimed in claim 1, wherein the protective support column tubes are attached to a central portion of the loading table.

3. The loading table structure as claimed in claim 1, wherein one or more functional rod members are received in said each of the protective support column tubes.

4. The loading table structure as claimed in claim 1, wherein the functional rod member is a heater feeding rod electrically connected to the heating means.

5. The loading table structure as claimed in claim 1, wherein a chuck electrode for electro-statically chucking the object to be processed loaded on the loading table is provided at the loading table, and the functional rod member is a chuck feeding rod electrically connected to the chuck electrode.

6. The loading table structure as claimed in claim 1, wherein a high frequency electrode for applying a high frequency electric power to the object to be processed loaded on the loading table is provided at the loading table, and the functional rod member is a high frequency feeding rod electrically connected to the high frequency electrode.

7. The loading table structure as claimed in claim 1, wherein a multi-use electrode for electro-statically chucking the object to be processed loaded on the loading table and applying a high frequency electric power to the object to be processed loaded on the loading table is provided at the loading table, and the functional rod member is a multi-use feeding rod electrically connected to the multi-use electrode.

8. The loading table structure as claimed in claim 1, wherein the functional rod member is a thermocouple for measuring a temperature of the loading table.

9. The loading table structure as claimed in claim 8, wherein the loading table comprises a loading table body and a thermal diffusion plate, which is installed at an upper surface of the loading table body and is formed of an opaque dielectric material different from a dielectric material forming the loading table body,
the heating means is installed within the loading table body, and
an attachment plate shaped like a metal plate is embedded in the thermal diffusion plate and a distal end of the thermocouple is brazed to the attachment plate.

10. The loading table structure as claimed in claim 9, wherein a connection hole, through which the thermocouple is inserted, is formed at a lower surface of the thermal diffusion plate.

11. The loading table structure as claimed in claim 8, wherein the loading table comprises a loading table body and a thermal diffusion plate, which is installed at an upper surface of the loading table body and is formed of an opaque dielectric material different from a dielectric material forming the loading table body,
the heating means is installed within the loading table body, and
an attachment plate shaped like a metal plate is embedded in the thermal diffusion plate, a metal auxiliary heat conductive member protruding downward beyond a lower surface of the thermal diffusion plate is brazed to the lower surface of the thermal diffusion plate, and a distal end of the thermocouple is brazed to the metal auxiliary heat conductive member.

12. The loading table structure as claimed in claim 11, wherein a thermocouple hole, in which a distal end of the thermocouple is inserted, is formed at the auxiliary heat conductive member.

13. The loading table structure as claimed in claim 11, wherein a connection hole, in which the auxiliary heat conductive member is inserted, is formed at a lower surface of the thermal diffusion plate.

14. The loading table structure as claimed in claim 11, wherein the distal end of the thermocouple is in forced contact with the auxiliary heat conductive member by a biasing force.

15. The loading table structure as claimed in claim 1, wherein the functional rod member is an optical fiber connected to a radiation thermometer to measure a temperature of the loading table.

16. The loading table structure as claimed in claim 1, wherein the loading table comprises a loading table body and a thermal diffusion plate, which is installed at an upper surface of the loading table body and is formed of an opaque dielectric material different from a dielectric material forming the loading table body, and
the heating means is installed within the loading table body.

17. The loading table structure as claimed in claim 16, wherein one of a chuck electrode for electro-statically chucking the object to be processed loaded on the loading table body of the loading table, a high frequency electrode for applying a high frequency electric power to the object to be processed, and a multi-use electrode for electro-statically chucking the object to be processed and applying a high frequency electric power to the object to be processed is installed within the thermal diffusion plate.

18. The loading table structure as claimed in claim 16, wherein the loading table body is formed of quartz, the thermal diffusion plate is formed of a ceramic material, and a protection plate formed of a ceramic material is provided on a surface of the loading table body.

19. The loading table structure as claimed in claim 16, wherein the loading table body and the thermal diffusion plate are integrally assembled with each other by an assembling member formed of a ceramic material.

20. The loading table structure as claimed in claim 16, wherein an inert gas is supplied to a portion between the loading table body and the thermal diffusion plate.

21. The loading table structure as claimed in claim 1, wherein the dielectric material is quartz or ceramic.

22. The loading table structure as claimed in claim 1, wherein the loading table and the protective support column tubes are formed of an identical dielectric material.

23. The loading table structure as claimed in claim 1, wherein an inert gas is supplied into the protective support column tubes.

24. The loading table structure as claimed in claim 1, wherein an inert gas is filled in the protective support column tube while lower ends of the protective support column tubes are sealed.

25. The loading table structure as claimed in claim 1, wherein pin inserting through-holes, through which push-up pins for moving the object to be processed upward and downward are inserted, are formed through the loading table,
a pin inserting through-hole purge gas supplying means having a pin inserting through-hole gas passage for supplying a pin inserting through-hole purge gas to the pin inserting through-holes from outside of the processing container is connected to the pin inserting through-holes, and
the protective support column tubes serve as a part of the pin inserting through-hole gas passage, so as to allow the pin inserting through-hole purge gas having been supplied from the outside of the processing container to flow through the protective support column tubes.

26. The loading table structure as claimed in claim 25, wherein the loading table comprises a loading table body and a thermal diffusion plate, which is installed at an upper surface of the loading table body and is formed of an opaque dielectric material different from a dielectric material forming the loading table body,
the loading table body and the thermal diffusion plate are detachably assembled with each other by loading table bolts formed of ceramic, and
the pin inserting through-holes longitudinally extend through the loading table bolts, respectively.

27. The loading table structure as claimed in claim 26, wherein each of the loading table bolts has a gas injection hole for interconnecting the pin inserting through-holes and the pin inserting through-hole gas passage.

28. The loading table structure as claimed in claim 27, wherein the gas injection hole is formed at a position higher than a longitudinal center of the support table bolt.

29. The loading table structure as claimed in claim 26, wherein body-side bolt holes, through which the loading table bolts are inserted, are formed through the loading table body, and
an around-bolt gap, through which the pin inserting through-hole purge gas passes, is formed between the support table bolt and the body-side bolt hole.

30. The loading table structure as claimed in claim 29, wherein the pin inserting through-hole gas passage is formed between the loading table body and the thermal diffusion plate, and has a gas storage space for temporarily storing the pin inserting through-hole purge gas.

31. A device for processing an object to be processed, the device comprising:
a processing container capable of discharging a gas in the processing container;
a loading table structure configured to load the object on the loading table structure, the loading table structure being installed within the processing container; and
a gas supplying means configured to supply the gas into the processing container, wherein the loading table structure comprises:
a loading table to load the object on the loading table, the loading table being formed of a dielectric material;
a heating means to heat the object loaded on the loading table, the heating means being installed at the loading table;
a plurality of protective support column tubes standing upright on a bottom portion of the processing container, each of the protective support column tubes having an upper end attached to a lower surface of the loading table, the protective support column tubes supporting the loading table and being formed of a dielectric material; and a functional rod member inserted into each of the protective support column tubes, and extending to the loading table.
